(19) United States
(12) Patent Application Publication
(10) Pub. No.: US 2014/0172186 A1
(43) Pub. Date: Jun. 19, 2014

(54) CAPACITIVE STEERING WHEEL SWITCHES WITH AUDIBLE FEEDBACK

(71) Applicants: Michael Mashkevich, West Bloomfield, MI (US); Jeffrey C. Hendry, Waterford, MI (US)

(72) Inventors: Michael Mashkevich, West Bloomfield, MI (US); Jeffrey C. Hendry, Waterford, MI (US)

(21) Appl. No.: 13/720,206

(22) Filed: Dec. 19, 2012

(51) Int. Cl. B60Q 9/00; H03K 17/96; G05G 1/00

(52) U.S. Cl. CPC B60Q 9/00; G05G 1/00; H03K 17/962
USPC 701/1; 74/491; 200/600

(57) ABSTRACT

A vehicle system including a switch assembly for actuating a device having predetermined function, and a notification assembly in communication with the switch assembly. The switch assembly includes a first switch and a second switch. The first switch is in communication with the notification assembly, and the second switch is in communication with the device. Upon actuation of the first switch, the notification assembly provides a signal that identifies the predetermined function of the device, and upon actuation of the second switch, the device performs the predetermined function.

### FIELD

The present disclosure relates to capacitive switches with audible feedback.

### BACKGROUND

This section provides background information related to the present disclosure which is not necessarily prior art.

As technology has progressed, more and more features are being incorporated into vehicles. For example, in addition to features such as powered windows and locks, vehicles may now be equipped with infotainment systems, navigation systems, and touch-screen radios. Each of these systems provide the driver or vehicle occupant with a number of different switches that, when the driver is looking for a particular switch to engage, may draw the driver's attention away from the road. Therefore, improvement in the art is desirable.

### SUMMARY

The present disclosure provides a vehicle system including a switch assembly for actuating a device having predetermined function, and a notification assembly in communication with the switch assembly. The switch assembly includes a first switch and a second switch. The first switch is in communication with the notification assembly, and the second switch is in communication with the device. Upon actuation of the first switch, the notification assembly provides a signal that identifies the predetermined function of the device, and upon actuation of the second switch, the device performs the predetermined function.

Further areas of applicability will become apparent from the description provided herein. The description and specific examples in this summary are intended for purposes of illustration only and are not intended to limit the scope of the present disclosure.

### DRAWINGS

FIG. 1 illustrates an exemplary interior of a motor vehicle including a plurality of buttons and knobs that each have a predetermined function, according to a principle of the present disclosure;

FIG. 2 illustrates the steering wheel assembly of FIG. 1, including a plurality of buttons that each have a predetermined function;

FIG. 3 illustrates an exemplary button that is operable to engage a switch assembly including a first switch and a second switch that may be used in accordance with the present disclosure; and

FIG. 4 illustrates the second switch of the switch assembly illustrated in FIG. 3.

### DETAILED DESCRIPTION

The present disclosure is directed to providing a vehicle with switches that, upon contact by the driver or an occupant of the vehicle, can identify to the driver or the occupant of the vehicle the switch's function. For example, upon contact with a switch that controls a volume of the vehicle's radio, an audible response will alert the driver or vehicle occupant that the switch is a volume switch. Alternatively, for example, upon contact with the switch, a visual response can alert the driver or vehicle occupant that the switch is a volume switch. Upon being notified of the switch's function, the driver or occupant can then mechanically actuate the switch. To provide the audible feedback, each switch can include a capacitive switch in addition to the mechanical switch. If audible or visual feedback is not desired, the feedback function of each switch can be turned off at an electronic vehicle information center (EVIC). It is desirable for the driver to be able to identify a switch without his or her attention being diverted from the road

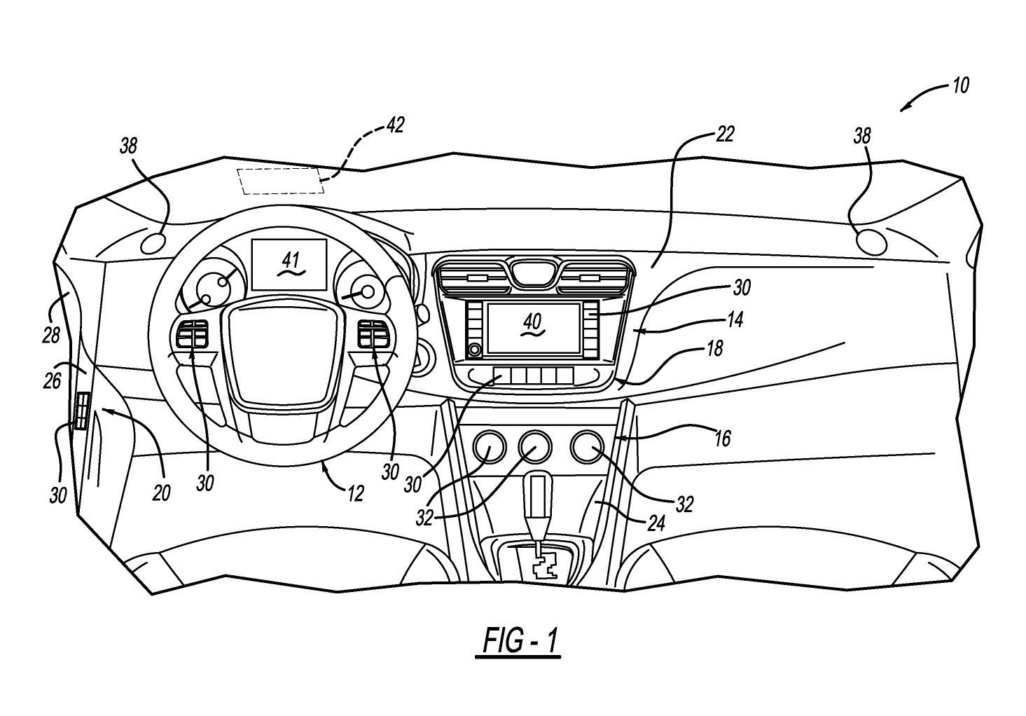

FIG. 1 illustrates an interior 10 of an exemplary motor vehicle. Interior 10 may include a steering wheel assembly 12, an infotainment or navigation system 14, a climate control system 16, a seat climate control system 18, and a window control system 20. Infotainment or navigation system 14, as well as seat climate control system 18, may be located in a dashboard 22 of interior 10. Climate control system 16 may be located in a center console 24. Window control system 20 may be located on an armrest 26 of a vehicle door 28. It should be understood, however, that each of the above-noted systems can be placed at different locations. For example, window control system 26 may be placed at center console 24, without departing from the scope of the present disclosure.

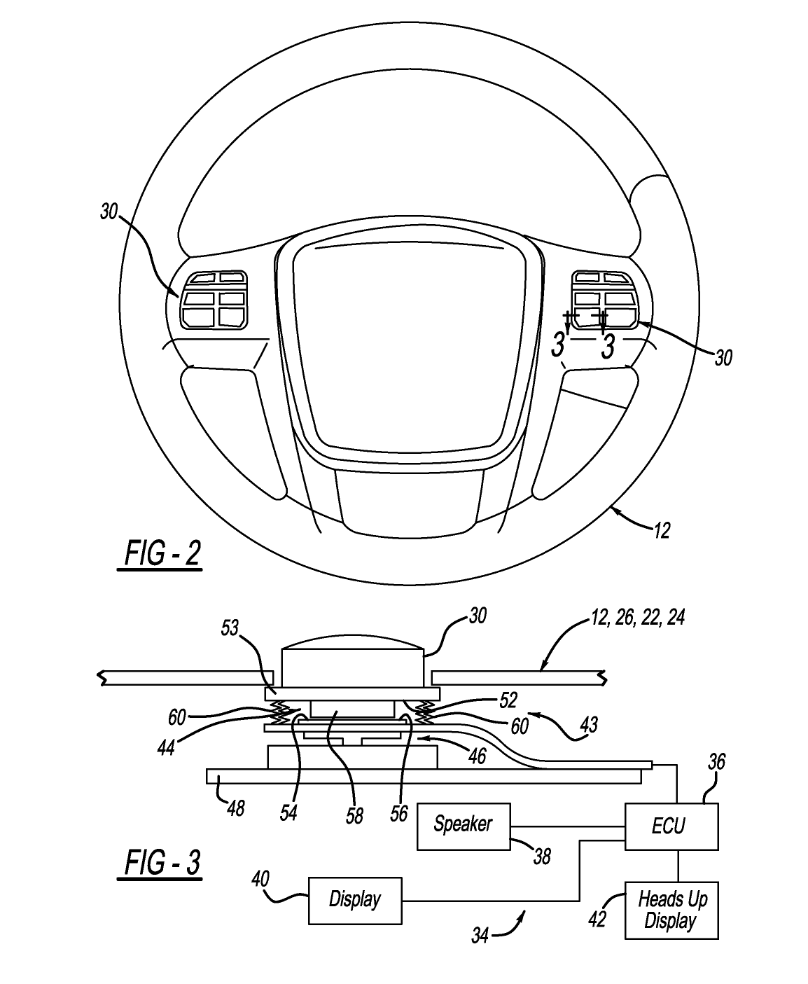

As best shown in FIG. 2, steering wheel assembly 12 may include a plurality of function controllers or buttons 30. Buttons 30 may be used to control a plurality of different systems including, but not limited to, a cruise-control system, a hands-free calling system, a headlamp-control system, window washing system, and a radio control system (e.g., volume and channel control switches). It should be understood, however, that buttons 30 can be placed at different locations throughout interior 10 such as dashboard 22, center console 24, or armrest 26 without departing from the scope of the present disclosure.

Similar to steering wheel assembly 12, each of systems 14, 18, and 20 can include a plurality of buttons 30. Although climate control system 16 is illustrated as including rotary knobs 32, it should be understood that rotary knobs 32 also function in a manner similar to function controllers or buttons 30. Accordingly, the use of the term “knob” or “button” in the present disclosure should be considered synonymous with the phrase “function controller.” Regardless, as illustrated in FIG. 1, a vehicle can include a plurality of systems 14, 16, 18, 20 that each may include a plurality of knobs 32 or buttons 30. Due to the large number of knobs 32 and buttons 30 in the interior 10 of the vehicle, it can be difficult for the driver to determine the function of button 30 or knob 32, without first taking his or her attention away from the road to focus on the particular button 30 or knob 32.

As best shown in FIG. 3, to ensure that the driver of the vehicle is able to keep his or her focus on driving as much as possible, each button 30 is in communication with a notification assembly 34. Notification assembly 34 may include an electronic control unit (ECU) 36 that may communicate with at least one of a speaker 38, a display 40 (e.g., a display of the infotainment or navigation system 14), an electronic vehicle information center (EVIC) 41, or a heads-up display 42 that can display a hologram in the driver's field of vision while driving.

Upon contact with button 30, a signal may be sent to ECU 36. Upon receipt of the signal from either button 30, ECU 36 can determine the function of the button 30, and send a signal to alert the driver of the function of the button 30. That is, ECU can send a signal to at least one of speaker 38, display 40, EVIC 41, or heads-up display 42 that will inform the driver of the function of the particular button 30 being touched.

If a signal is sent from ECU 36 to speaker 38, speaker 38 can audibly alert the driver of the function of the button 30. Alternatively or in addition to, if a signal is sent from ECU 36 to any of display 40, EVIC 41, or heads-up display 42, the display 40, EVIC 41, or heads-up display 42 can visually display the function of the button 30. For example, if a volume switch is touched by the driver or an occupant in the vehicle, speaker 38 can audibly state “volume” to alert the driver that the particular button 30 functions as a volume control, or displays 40, 42 and EVIC 41 can visually display the word “volume.” In this manner, the driver can be alerted to the function of the button 30 without diverting his or her attention from driving.

Additional information can also be provided by to the driver or vehicle occupant. For example, if a volume switch is touched by the driver or an occupant in the vehicle, speaker 38 can audibly state “volume up” or “volume down” if that is the particular button 30 that is engaged. Another example is window control system 20 that may include a plurality of buttons 30 that each correspond to a particular window. Instead of being alerted that button 30 is for a “window,” the notification assembly 34 can alert the driver or vehicle occupant that a “driver-side window,” “passenger-side window,” “rear driver-side window,” or a “rear passenger-side window” button 30 has been engaged. Regardless, it should be appreciated that notification assembly 34 can be designed and operable to provide any type of information to the driver or vehicle occupant.

Each button 30 can be considered a “switch assembly” 43 that can include a first switch 44 and a second switch 46. Each button 30 can include a first switch 44 and a second switch 46 such that upon actuation of first switch 44, notification assembly 34 can provide a signal that identifies the predetermined function of the button 30, and upon actuation of second switch 46, button 30 performs the predetermined function.

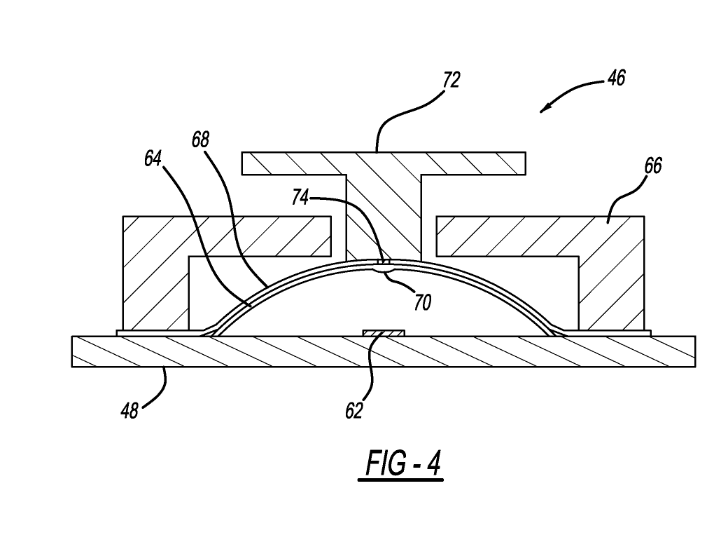

More specifically, first switch 44 may be capacitive, while second switch 46 may be mechanical. Such an arrangement allows the driver or occupant of the vehicle to touch the button 30 to engage first switch 44 and be alerted to the function of the button 30 without engaging the second switch 46 and allowing the button 30 to perform its predetermined function. As illustrated in FIGS. 3 and 4, switch assembly 43 can be disposed on a wiring board 48 including a wiring 50, which provides electrical communication between switch assembly 43 and ECU 36 of notification assembly 34.

To provide electrical contact between switch assembly 43 and ECU 36, button 30 can be formed of a dielectric material. A lower surface 52 of button 30 faces the upper surface 54 of a capacitive pad 56. A projection 58 is formed on the lower surface 52 of the button 30. When the button 30 is depressed, the projection 58 comes into contact with the upper surface 54 of the capacitive pad 56. The button 30 is positioned over the capacitive pad 56 by springs 60, which are disposed between the button 30 and the capacitive pad 56 and make button 30 movably supported relative to steering wheel assembly 12, dashboard 22, center console 24, or armrest 26 where the button 30 is located. When the button 30 is not depressed, a clearance is present between projection 58 and capacitive pad 56. When button 30 is depressed, projection 58 is operable to come into contact with capacitive pad 56.

Accordingly, to operate the switch assembly 43, the driver or occupant of the vehicle can contact the button 30 to bring projection 58 into contact with capacitive pad 56, which results in a change in capacitance. As a result of the change in capacitance, a first signal is output through wiring 50 to ECU 36. When the first signal is received by ECU 36, ECU 36 can then instruct speaker 38 and/or displays 40, 42, or EVIC 41 to alert the driver or occupant of the function of the button 30. If speaker 38 is used to alert the driver or occupant, an audible signal alerts the driver. If displays 40, 42 or EVIC 41 are used to alert the driver or occupant, a visual signal alerts the driver. In this manner, the driver can simply touch a button 30 without diverting his or her attention from driving and be informed of the particular function of the button 30.

After being informed of the function of the button 30, the driver or occupant may determine whether to allow the button 30 to perform its intended function. To enable button 30 to conduct its predetermined function, second switch 46 must be engaged. As best shown in FIG. 4, second switch 46 includes a fixed electrode 62 that is printed on wiring board 48.

A tactile spring 64 is mounted on the wiring board 48, with a periphery of the tactile spring 64 being held by a housing 66 that protects tactile spring 64 and fixed electrode 62. Additionally, a covering layer 68 can be used to cover and protect the tactile spring 64. The tactile spring 64 can be inverted and functions as a metallic contact (movable contact). When a center 70 of the tactile spring 64 is inverted, the tactile spring 64 comes into contact with the fixed electrode 62. To invert the tactile spring 64, second switch 46 also includes a movable operating member 72 that is disposed over and fixed to the covering layer 68 with an adhesive 74. Upon application of a force to operating member 72 from compression of springs 60 upon application of a force by the driver or vehicle occupant, force can be transferred through first switch 44 to tactile spring 64 which is then inverted to contact fixed electrode 62. Upon contact with fixed electrode 62, the predetermined function of the button 30 can be performed.

Although the above description was relative to a button 30, it should be understood that knobs 32 can be configured in a similar manner. Knobs 32, however, would not include second switch 46. Rather, knob 32 would be coupled to a base member 53, at a surface 52 of which includes projection 58. Upon application of a force by the driver or vehicle occupant to knob 32, projection 58 can contact capacitive pad 56 to communicate with notification assembly 34. After being notified of the function of knob 32, the driver or vehicle occupant can then merely rotate knob 32 as is known in the art to effect operation thereof.

Lastly, it should be understood that the above-noted description of button 30 and knob 32 is merely exemplary in nature. That is, any type of capacitive and mechanical switches may be used in conjunction with either button 30 or knob 32 without departing from the scope of the present disclosure so long as the capacitive switch is in turn coupled to notification assembly 34.

What is claimed is:

1. A vehicle system, comprising:
a switch assembly for actuating a device having predetermined function; and
a notification assembly in communication with the switch assembly,
wherein the switch assembly includes a first switch and a second switch, the first switch being in communication with the notification assembly, and the second switch being in communication with the device; and
upon actuation of the first switch, the notification assembly provides a signal that identifies the predetermined function of the device, and
upon actuation of the second switch, the device performs the predetermined function.

2. The vehicle system of claim 1, wherein the first switch is a capacitive switch.

3. The vehicle system of claim 1, wherein the second switch is a mechanical switch.

4. The vehicle system of claim 1, wherein the notification assembly includes an electronic control unit.

5. The vehicle system of claim 1, wherein the notification assembly includes a display.

6. The vehicle system of claim 1, wherein the notification assembly includes a speaker.

7. The vehicle system of claim 1, wherein the signal is audible.

8. The vehicle system of claim 1, wherein the signal is visual.

9. The vehicle system of claim 8, wherein the visual signal is a hologram displayed in a heads-up display.

10. The vehicle system of claim 1, wherein the switch assembly is provided in a steering wheel.

11. The vehicle system of claim 1, wherein the notification system includes an electronic vehicle information center (EVIC).

12. A vehicle system, comprising:
an electronic control unit;
a plurality of switch assemblies in communication with the electronic control unit;
a plurality of devices having predetermined functions in communication with at least one of the plurality of switch assemblies; and
a notification system in communication with the electronic control unit,
wherein each of the switch assemblies is operable in a first state and a second state, the first state sending a signal to the electronic control unit,
upon receipt of the first signal, the electronic control unit will instruct the notification system to identify the predetermined function of the corresponding device, and
in the second state, the switch assembly allows the device to perform the predetermined function.

13. The vehicle system of claim 12, wherein the first signal is sent by a capacitive sensor.

14. The vehicle system of claim 12, wherein the notification assembly includes a display.

15. The vehicle system of claim 12, wherein the notification assembly includes a speaker.

16. The vehicle system of claim 12, wherein the identification provided by the notification system is audible.

17. The vehicle system of claim 12, wherein the identification provided by the notification system visual.

18. The vehicle system of claim 17, wherein the visual signal is a hologram displayed in a heads-up display.

19. The vehicle system of claim 12, wherein the switch assembly is provided in a steering wheel.

20. The vehicle system of claim 12, wherein the notification assembly includes an electronic vehicle information center.
